(19) United States
(12) Patent Application Publication
(10) Pub. No.: US 2008/0204282 A1
(43) Pub. Date: Aug. 28, 2008

(54) Character Input Device for Terminal and Method of Processing Character String

(76) Inventor: Han Koo Jeon, Anyang-si (KR)

Correspondence Address: PARK LAW FIRM, 3255 WILSHIRE BLVD, SUITE 1110, LOS ANGELES, CA, 90010, US

(21) Appl. No.: 12/088,746

(22) PCT Filed: Oct. 23, 2006
(86) PCT No.: PCT/KR2006/004323

§ 371 Date: Mar. 31, 2008

(30) Foreign Application Priority Data
Oct. 25, 2005 (KR) 10-2005-0100753

(51) Int. Cl. H03M 11/04

(52) U.S. Cl. 341/22; 341/28

(57) ABSTRACT

The present invention discloses a character input device for a terminal and a method of processing a character string, which allow the size of the character input device to be sufficiently reduced so as to improve the portability of the terminal, enable rapid and accurate character input in a touch typing fashion even in a mobile environment, and can minimize the number of presses of each key for the input of each character The character input device for a terminal includes a plurality of character keys and a function key, wherein the character keys include a character arrangement corresponding a first half of a “Sholes” character arrangement with respect to a center of the “Sholes” character arrangement, a character arrangement of a second half of the “Sholes” character arrangement being arranged on the character keys at locations mirror- image symmetrical to the first half with respect to the center of the “Sholes” character arrangement.

### TECHNICAL FIELD

The present invention relates to a character input device provided in a mobile phone, a PDA, a notebook computer, a car navigation apparatus, or the like, and to a method of processing a character string input through the character input device.

### BACKGROUND ART

Recently, with the rapid development of electronic equipment-related technology, portable terminals, which provide various functions, continue to appear. The size of terminals, which is a principle factor to consider for portability, trends toward reduction in connection with the evolution of related technology and consumers' demand. At the present time, it is no exaggeration to say that the key point governing reduction in size resides in the structure of a character input device provided in a terminal.

A keyboard that is reduced in size (reduced at a specific ratio) and has a ‘QWERTY’ arrangement is taken as an example of a conventional character input device for a terminal. This keyboard is constructed by reducing a keyboard, which is generally and widely used as a character input device for a computer and has a ‘Sholes’ arrangement, to a size suitable for the size of a mobile terminal. As the overall size is reduced at a specific ratio, a user commonly takes a method of inputting a specific character string by pressing key buttons using the thumb while holding both sides of the terminal with two hands. Since a keyboard having the above-described structure employs the arrangement of a computer keyboard as it is, it is advantageous in that it is not necessary to learn a new character layout. However, since the locations of key buttons reduced in size as described above are checked using the eyes and are pressed using the thumb, there are problems in that the rapid input of characters cannot be expected and use while moving is inconvenient.

For reference, the keyboard of a computer, in other words, a keyboard having a ‘Sholes’ arrangement, shown in FIG. 1, enables touch typing. Here, the term “touch typing” refers to a method in which a user has been accustomed to a character input structure and rapidly inputs characters using the sense of touch of the fingers without viewing respective key buttons to which characters have been assigned. Touch typing is considered important in a mobile environment. The reason for this is that there are many cases where a user holds a terminal with one hand and observes his or her surroundings rather than fixing his or her eyes on the terminal while moving, unlike the case where a user inputs characters at a fixed location. If a user can input characters through touch typing during movement while directing his or her eyes forward or on the surroundings, it is apparent that touch typing can act as a factor for maximizing the utility of a mobile terminal.

Meanwhile, another example of the conventional character input device for a mobile terminal is a character input scheme using the numeric keypad of a wired/wireless telephone, which is illustrated in FIG. 2. As is well known, this scheme is a scheme of assigning the English alphabet or Korean alphabet to the numeric keypad and inputting characters. Since the numeric keypad of a telephone has 10 numeral keys due to the structure thereof and, among the ten keys, the key corresponding to ‘0’ is used for a special purpose, all of the characters are assigned to a total of nine numeral keys. As a result, which key has been pressed must be determined, and the following methods are used to determine which key has been pressed.

First, there is a method in which a user definitely designates the character to be input. For example, this method is a method in which character ‘A’ is input when key ‘2’, to which characters ‘A’, ‘B’ and ‘C’ have been assigned, is pressed once, character ‘B’ is input when the key ‘2’ is pressed twice, and character ‘C’ is input when the key ‘2’ is pressed three times. This method is disadvantageous in that the character input speed is lowered considerably because the same key must be pressed many times, and furthermore, a subsequent character must be input after a cursor has been moved to the input location of a subsequent character by pressing a predetermined direction key or after waiting until a predetermined time period has elapsed, in the case where characters assigned to the same key (for example, ‘J’, ‘K’ or ‘L’, assigned to key ‘5’) must be successively input.

Second, there is a method in which an input character is determined by a system itself, other than a user, in the case where a key to which a plurality of characters has been assigned is pressed. A user inputs a character string by pressing each key once regardless of which of the characters assigned to the corresponding key is input. In this case, since a plurality of characters has been assigned to a single button, a plurality of combination character strings is formed. For example, when the character string desired to be input is ‘PAT’, keys ‘7’, ‘2’ and ‘8’ are pressed. Since the keys are respectively assigned ‘P’, ‘R’ and ‘S’, ‘A’, ‘B’ and ‘C’, and ‘T’, ‘U’ and ‘V’, a total of 27 combination character strings can be formed. Each of the combination character strings is compared with the words in the word database stored in the system, only significant combination character strings corresponding to words are left and the other character strings are discarded, and a user is allowed to finally select one in the case where a plurality of combination character strings remains.

This method has improved character input speed, compared to the above-described first method, because a user presses a key, to which a character is assigned, once so as to input the corresponding character, but this method does not provide sufficiently fast input speed, compared to a computer keyboard (a keyboard having a ‘Sholes’ arrangement), because the numeric keypad structure of a telephone is still used, and therefore a user must input characters using the thumb or index finger. Furthermore, since it is difficult for a user to achieve complete mastery of the arrangement of characters assigned to keys, and since characters can be input using only one or more fingers, even if the user achieves complete mastery of the arrangement, the user must always observe the keys while inputting characters. As a result, this method also has poor utility in a mobile environment, like the first method.

### DISCLOSURE

### [Technical Problem]

Accordingly, the present invention has been made keeping in mind the above problems occurring in the prior art, and an object of the present invention is to provide a character input device for a terminal and a method of processing a character string, which allow the size of the character input device to be sufficiently reduced so as to improve the portability of the terminal, enable rapid and accurate character input in a touch typing fashion even in a mobile environment, and can minimize the number of presses of each key for the input of each character.

Furthermore, another object of the present invention is to provide a character input device for a terminal, which employs a character arrangement having a mirror-image vertical symmetry based on a ‘Sholes’ character arrangement, therefore a user can easily grasp the usage method thereof.

### [Technical Solution]

In order to accomplish the above objects, the present invention provides a character input device for a terminal, including a plurality of character keys and a function key, wherein the character keys include a character arrangement corresponding a first half of a ‘Sholes’ character arrangement with respect to a center of the ‘Sholes’ character arrangement, a character arrangement of a second half of the ‘Sholes’ character arrangement being arranged on the character keys at locations mirror-image symmetrical to the first half with respect to the center of the ‘Sholes’ character arrangement.

Preferably, an input character string may be processed through step S100 of adding characters, arranged on respective pressed keys, to a character string buffer when an English key sequence is input through the character input device; step S200 of generating combination character strings from the characters added to the character string buffer; step S300 of searching the word database for words matching corresponding combination character strings on an assumption that each of the generated combination character strings is a word having a prefix/stem/suffix combination, and generating a recommended word list using the matching corresponding combination character strings; and step S400 of displaying the generated recommended word list on a display device of the terminal.

Meanwhile, an input character string may be processed through step S10 of adding characters, arranged on respective pressed keys, to a character string buffer when a Korean key sequence is input through the character input device; step S20 of generating a combination character string tree from the characters added to the character string buffer; step S30 of examining whether combination character strings of the combination character string tree comply with a rule of vowel and consonant combination; step S70, if the combination character string does not comply with the rule of vowel and consonant combination, deleting a part of a tree below the combination character string, backtracking to a location of a most recent meaningful character string, selecting a subsequent combination character string, and then returning to the step S30; step S40 of, if the combination character string complies with the rule of vowel and consonant combination, searching the word database for a word that matches the assumed word on an assumption that the corresponding combination character string is a word having a prefix/stem/suffix combination; step S50 of determining whether there is a matching word at the step S40; step S60, if, as a result of the determination at step S50, there is a matching word, adding the corresponding character string to the recommended word list, and displaying the combination character string on a display device of the mobile terminal; and the step of, if, as a result of the determination at the step S50, there is no matching word, returning to the step S70.

### DESCRIPTION OF DRAWINGS

FIG. 1 is a view illustrating an example of a conventional keyboard having a ‘Sholes’ arrangement;

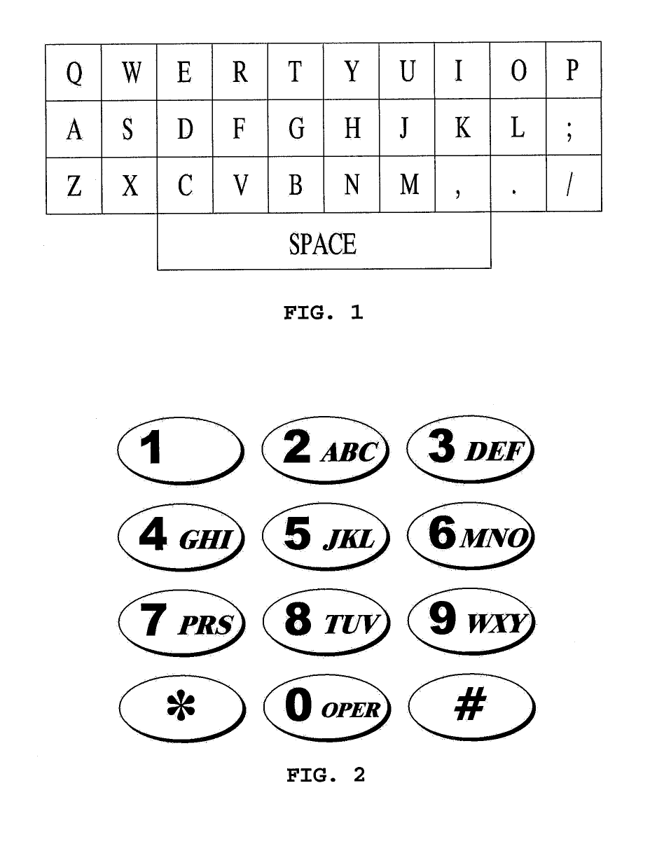

FIG. 2 is a view illustrating an example of the conventional numeric keypad of a wired/wireless telephone;

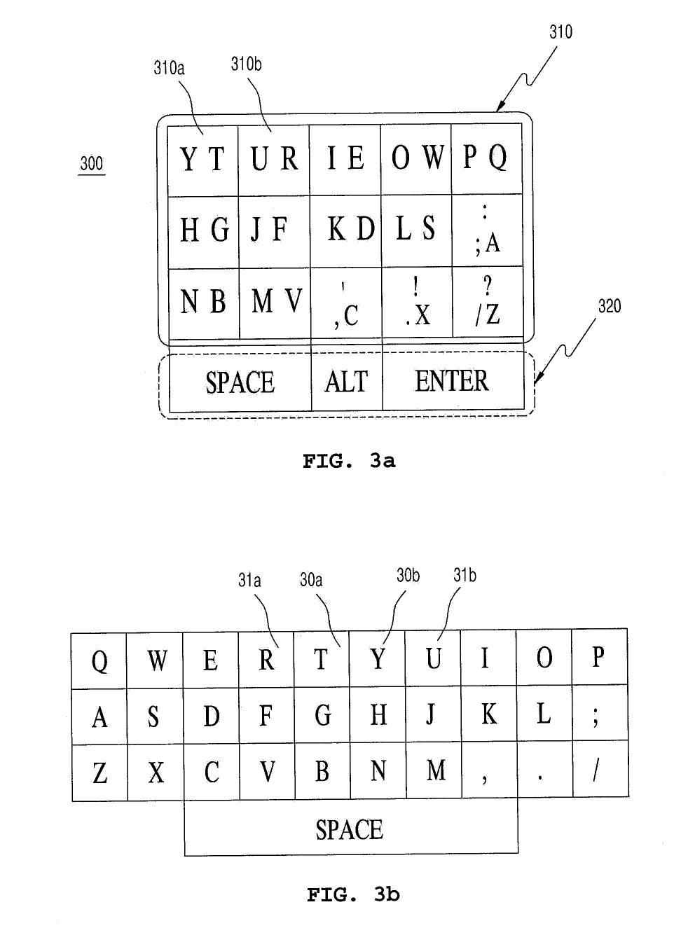

FIG. 3a is a view illustrating an example of a right hand-dedicated English character input device according to the present invention;

FIG. 3b is a view illustrating an example of the relationship between the conventional keyboard having a ‘Sholes’ arrangement and the character input device of FIG. 3a;

FIG. 4 is a view illustrating an example of a left hand-dedicated English character input device according to the present invention;

FIG. 5 is a view illustrating an example of a right hand-dedicated Korean character input device according to the present invention;

FIG. 6 is a view illustrating an example of a left hand-dedicated Korean character input device according to the present invention;

FIG. 7a is a view illustrating an example of a right hand-dedicated combination character input device according to the present invention;

FIG. 7b is a view illustrating an example of a left hand-dedicated combination character input device according to the present invention;

FIG. 8 is a configuration diagram illustrating a mobile terminal equipped with one or two character input devices according to the present invention;

FIG. 9 is a view illustrating an example of the structure of an English word;

FIG. 10 is a flowchart illustrating a process of generating an English recommended word list according to the present invention;

FIG. 11a is a detailed flowchart illustrating step S300 of FIG. 10;

FIGS. 11b to 11g are detailed flowcharts illustrating respective steps of FIG. 11a, respectively;

FIG. 12 is a flowchart illustrating a process of generating a Korean recommended word list according to the present invention; and

FIG. 13 is a view illustrating an example of the structure of a combination character string tree according to the present invention.

### DESCRIPTION OF REFERENCE CHARACTERS OF PRINCIPAL ELEMENTS

800: mobile terminal according to the present invention

810A: first character input device

810B: second character input device

820: memory

822: control program

824: word database

830: control module

### BEST MODE

The features and advantages of the present invention will be more apparent from the following detailed description based on the accompanying drawings. First, the terms and words used in the present specification and claims must be interpreted to comply with the technical spirit of the present invention based on the principle in which an inventor can define the concepts of terms in order to describe his or her invention in the best way. Furthermore, it should be noted that detailed descriptions are omitted below if it is determined that the detailed descriptions of well-known functions and constructions related to the present invention may make the gist of the present invention unclear.

When a character input device is applied to the above-described mobile terminal, most of attempts to disregard and completely change a well-known character arrangement may be ignored by users no matter how effective the mobile terminal is. The reason for this is that there are very few people who abandon a conventional character arrangement, to which they have been accustomed for a long time, and accept a new arrangement. Accordingly, the present invention uses the ‘Sholes’ character arrangement familiar to users, with the above fact being taken into consideration.

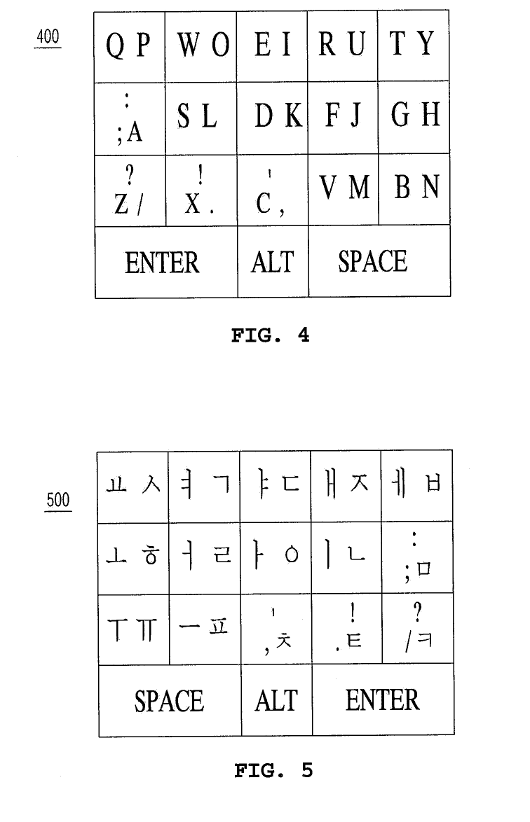

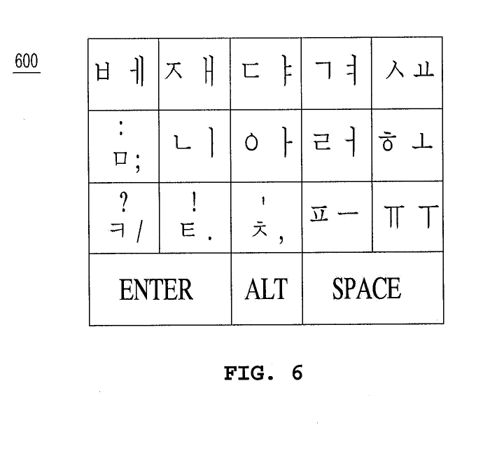

Hereinafter, a character input device for a terminal according to an embodiment of the present invention, to which a ‘Sholes’ character arrangement is applied, is described below. As illustrated in FIG. 3a, a character input device for a terminal 300 (hereinafter referred to as a ‘character input device’) is divided into a character key part 310 and a function key part 320 including keys ‘ALT’, ‘ENTER’ and ‘SPACE’.

Each key of the character key part 310 is assigned a pair of characters that are placed at locations having a mirror-image symmetry relationship with respect to the center of a typical ‘Sholes’ keyboard, as illustrated in FIG. 3b. For example, character ‘T’ of a key 30a and character ‘Y’ of a key 30b, which are opposite each other with respect to the center of the ‘Sholes’ keyboard, are assigned to a key 310a that is located at the left upper portion of the character key part 310, as illustrated in FIG. 3a, and character ‘R’ 31a, located to the left of the character ‘T’ 30a, and character ‘U’ 31b, located to the right of character ‘Y’, 30b are assigned to a key 310b, located to the right of the key 310a, to which characters ‘T’ and ‘Y’ are assigned. In the same manner, the keys of the ‘Sholes’ keyboard shown in FIG. 3b are arranged in the character key part 310 shown in FIG. 3a in a mirror-image symmetry manner.

In more detail, characters assigned to the corresponding fingers of both hands (for example, the index fingers of the right and left hands) in the conventional ‘Sholes’ keyboard are arranged on the keys 310a and 310b that correspond to the location of the same finger of one hand (in the present embodiment, the right hand), therefore both hands have a mirror-image symmetrical relationship. The reason for this is to enable touch typing to be performed using only the right hand, as in the embodiment of the present invention. Of course, in order to type characters, assigned to the left hand in the conventional keyboard, using only the right hand, some trial and error is required. However, considering that conventional touch typists (users accustomed to the conventional character arrangement) memorize the character arrangement (‘QWERTY’ arrangement) using the muscle memory of both fingers rather than their brains, the trial and error may be sufficiently reduced. In other words, the above-described character input device 300 of FIG. 3a can be considered to be a keyboard to which an optimal character arrangement that takes into account the mirror-image, vertical symmetry of both hands is applied.

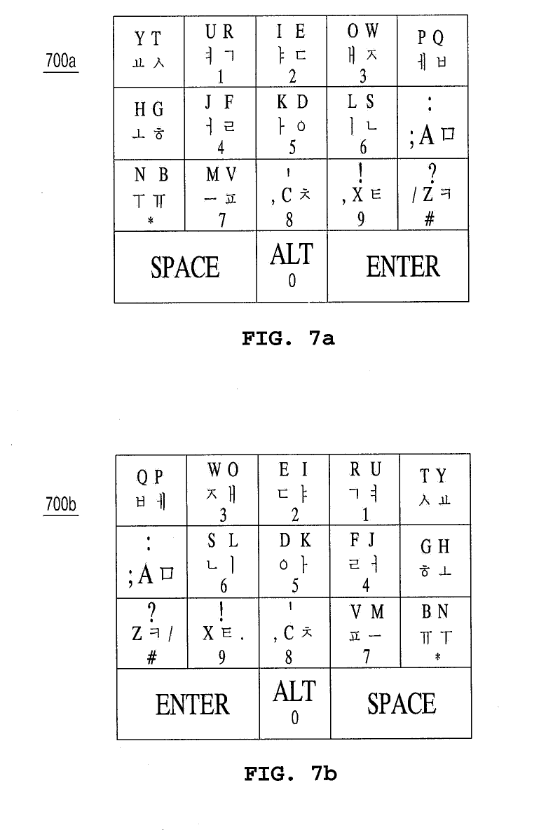

The above-described character input device 300 relates to a right hand-dedicated English character input device, and enables a user to perform touch typing using the right hand while holding a terminal, which employs the character input device 300, using the left hand. In a similar way, a left hand-dedicated English character input device 400 that enables a user to perform touch typing using the left hand while holding a terminal using the right hand, which is shown in FIG. 4, may be considered. Here, the left hand-dedicated English character input device 300 is symmetrical to the right hand-dedicated English character input device 400. A terminal provided with the character input device of the present invention may be switched between the right hand-dedicated mode and the left hand-dedicated mode.

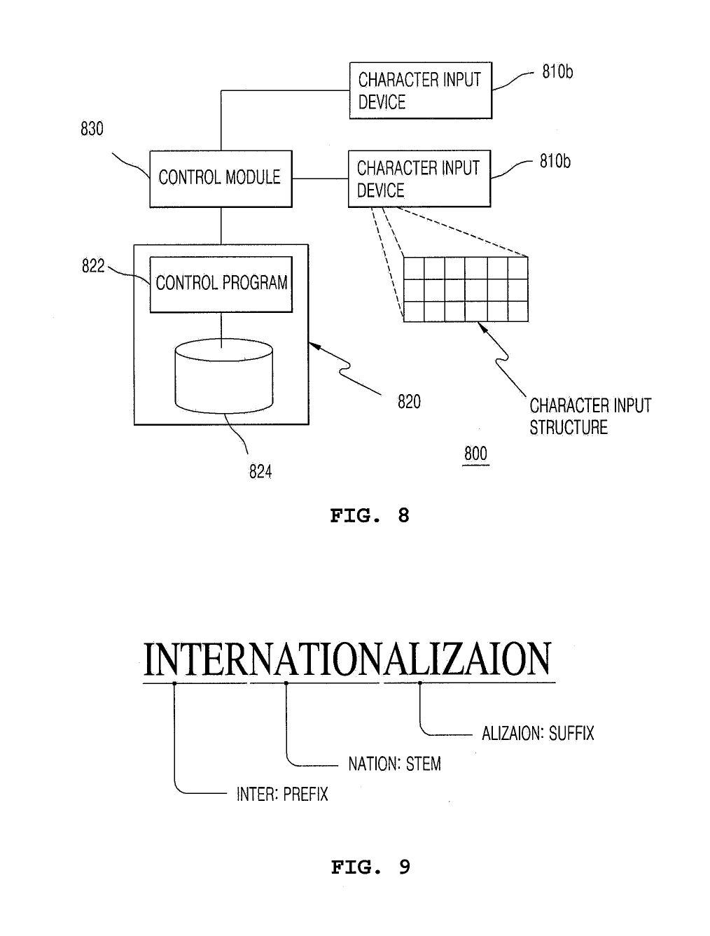

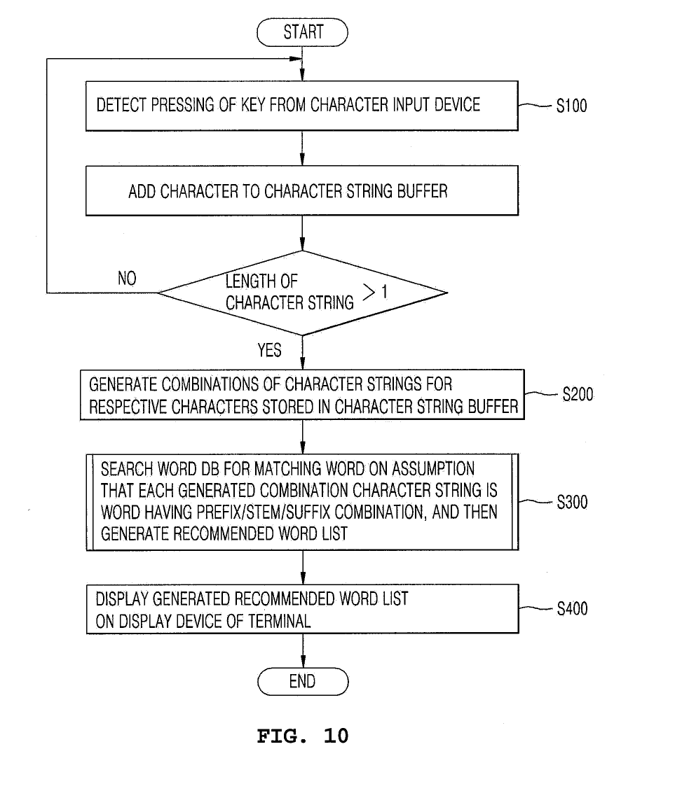

Although character input devices 300 and 400 for English have been discussed, the same scheme may be applied to the Korean alphabet. In the present embodiment, a Hangeul 2-set standard keyboard layout corresponding to the ‘Sholes’ character arrangement is a basis. A right hand-dedicated Korean character input device 500 and a left hand-dedicated Korean character input device 600 may be constructed, as shown in FIGS. 5 and 6.

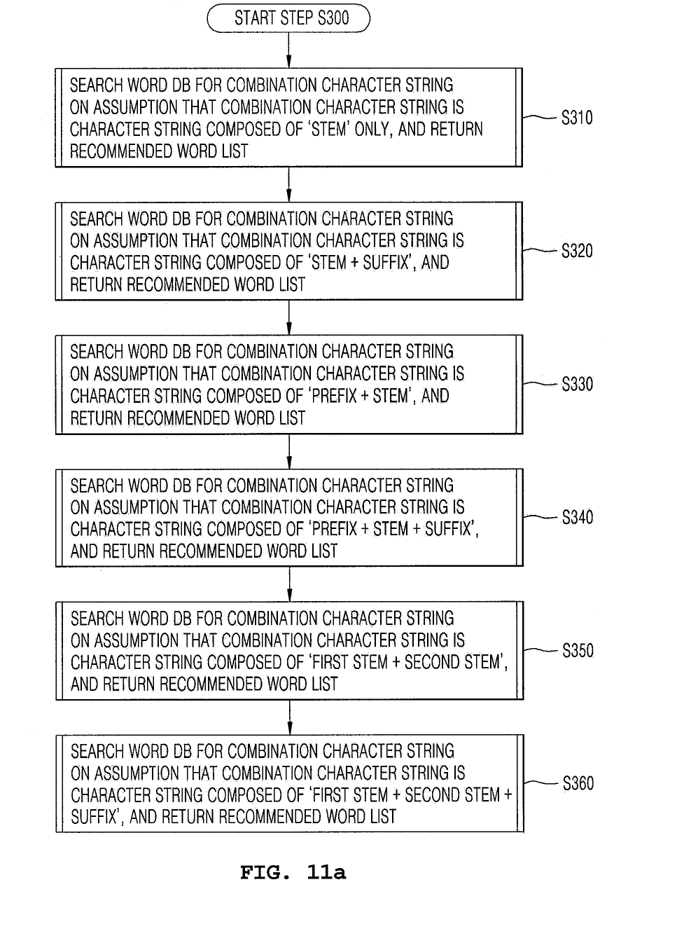

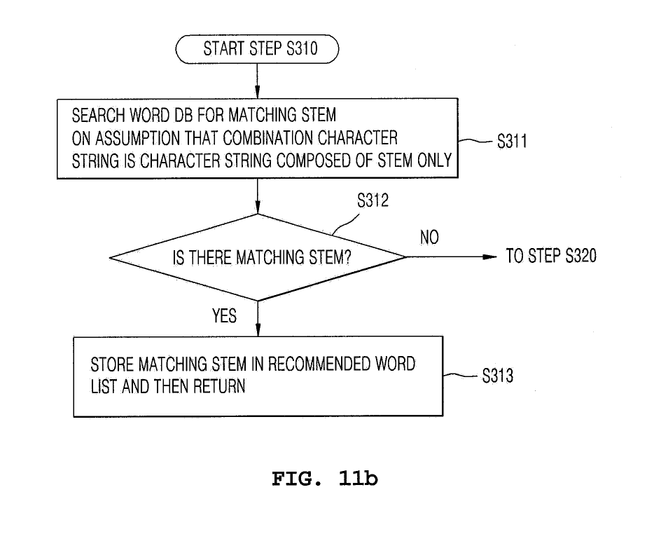

Furthermore, a character input device including the above-described English characters, Korean characters, and numerals 0˜9 may be considered. Preferably, switching between English character, Korean character and numeral input modes may be easily achieved using a specific switching key that may be added to the character input device as a function key. Moreover, switching between the right hand-dedicated input device and the left hand-dedicated character input device may be easily achieved through the control program of a terminal. A character input device composed of a combination of English characters, Korean characters and numerals (hereinafter referred to as a ‘combined character input device’) is as illustrated in FIGS. 7a and 7b. FIG. 7a illustrates a right hand-dedicated combination character input device 700a, and FIG. 7b illustrates a left hand-dedicated combination character input device 700b.

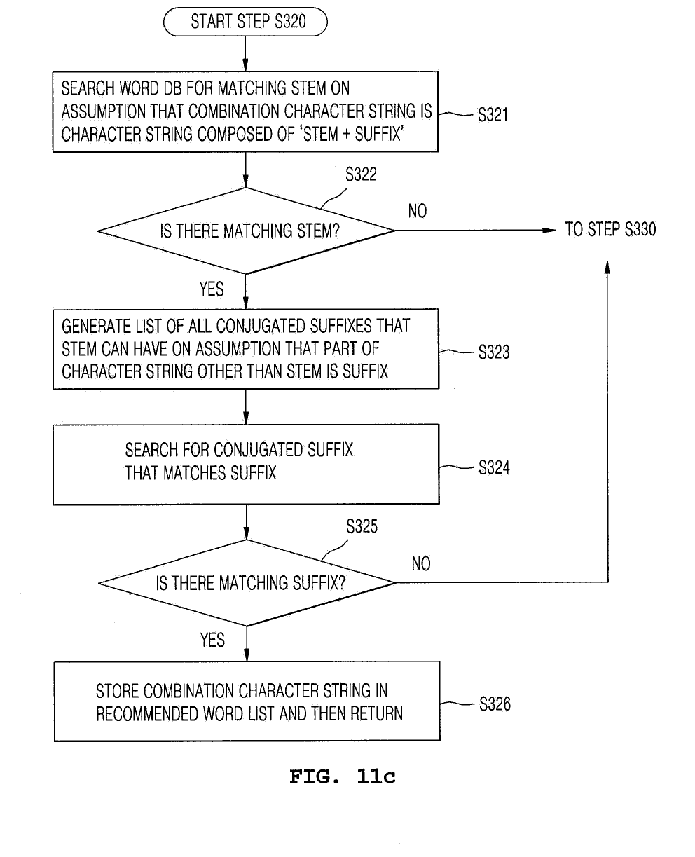

A character input device according to the present invention and a terminal using a terminal character input device are described in detail below with reference to FIG. 8. Referring to the drawing, a mobile terminal 800 according to the present invention includes a first character input device 810A; memory 820 including a control program 822 for controlling the first character input device 810A and a word database 824; and a control module 830 for controlling the character input device 810 based on the control program 822.

Here, the mobile terminal 800 further includes a detachable second character input device 810B, in which case the two character input devices 810A and 810B may be respectively set to a left hand-dedicated character input device and a right hand-dedicated character input device, and may be used as a full-sized ‘QWERTY’ keyboard. In the case where the two character input devices 810A and 810B are used, the mobile terminal 800 will be useful for vehicle terminals (navigation devices or computers) and general computers. In the case where the mobile terminal 800 is applied to a vehicle terminal, character input devices 810A and 810B may be placed on respective sides of a driver's seat; in the case where the mobile terminal 800 is applied to a notebook computer, the overall size of the character input devices may be reduced to a size suitable for a single character input device and may be used as a full-sized keyboard.

Meanwhile, as described above, a plurality of characters (m characters) is assigned to each of the keys of the character input devices 810A and 810B. Whenever a user presses a key, the number of character strings obtainable through combination increases m times. Assuming that two (m=2) characters are assigned to each key and the length of a character string input by a user is n, 2ⁿ character strings can be obtained. For example, in the case where a user inputs the word ‘FOR’, character strings obtainable through combination are ‘JOU’, ‘JOR’, ‘JWU’, ‘JWR’, ‘FOU’, ‘FOR’, ‘FWU’ and ‘FWR’, that is, a total of 2³=8 combination character strings.

If the length of an input character string increases, the number of character strings obtainable through combination increases in geometric progression. However, among such character strings obtained through combination, the number of significant character strings (character strings used as words in a current language system) is considerably low and the remaining character strings are merely insignificant simple arrangements of characters. As a result, in order to extract significant character strings from character strings, the number of which increases in geometric progression based on a user's input key sequence, the task of searching a word database 824 for character strings obtained through combination (combination character string), checking whether there is a matching word, and adding only a corresponding combination character string to a word list (hereinafter referred to as a ‘recommended word list’) if there is a matching word.

In a series of processes, the performance of the application (control program) used is a very important factor. The reason for this is that it is necessary to perform the task of comparing each of the combination character strings, the number of which increases in geometric progression whenever a key of the character input device 810A or 810B is pressed, with tens of thousands of words in the case where the total number of words in a word database 824 stored in the memory 820 is tens of thousands. Taking the problem of performance into consideration, the present invention assumes that the number of words used in real life is tens of thousands and chiefly aims to improve processing speed for searching so as to provide for the case where the performance of a processor (control module 830) used to implement the present invention is not high.

In more detail, it is difficult to expect to efficiently store tens of thousands of words in the word database 824 and check whether there is a word matching each of the combination character strings, generated by the pressing of a key, using the performance of a typical low specification processor for controlling a character input device. In order to solve the problem, the present invention employs a method of analyzing the elements of words and considerably reducing the number of words to be actually processed in the present invention.

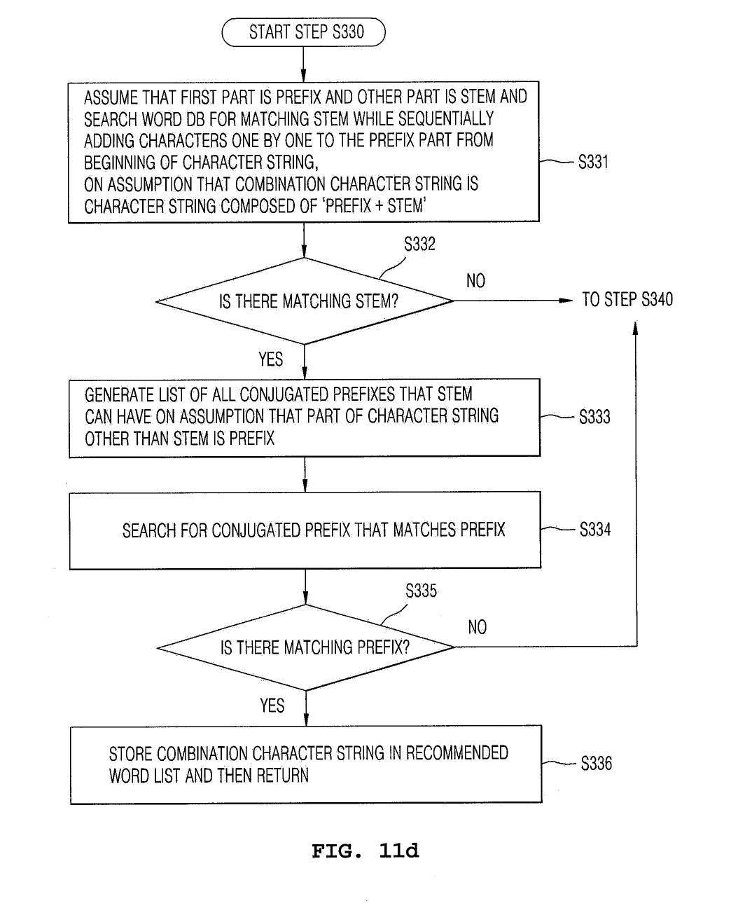

In order to implement the above method, the construction of typical words used in real life is discussed below. As illustrated in FIG. 9, the word ‘INTERNATIONALIZAION’ is a word having a conjugated form (hereinafter referred to as a ‘conjugated word’) that is obtained by adding the prefix ‘INTER’ and the suffix ‘ALIZATION’ to the stem ‘NATION’, which is not changed.

With the features of the construction of words taken into consideration, the word database 824 according to the present invention stores stems in a database form in advance and uses prefixes and suffixes, which can be combined with each stem, as conjugated prefixes and suffixes at the time of checking a character string for the specific stem. Unlike a desktop computer, for a mobile terminal, the size of memory therein is an important factor that should be considered in the design of the terminal, therefore it is necessary to reduce the size of the word database 824 as much as possible. Accordingly, as long as there is no problem with processing speed, the present invention employs a method of creating conjugated words during runtime as required and discarding the words after use, rather than storing the conjugated words, so as to prevent the size of memory for storing the word database 824 from increasing excessively. In the present embodiment, words stored in the word database 824 have stem forms, and it is preferred that DBs for prefixes and suffixes that the stems can have (a prefix DB and a suffix DB) be included.

For reference, assuming that there is an average of 10 conjugated words and the number of stems stored in the word database 824 is 10 thousand, the number of words that can be processed in the present invention is a total of 100 thousand (the number of stems×10). In reality, in the case of English, the number of conjugated words for each stem is greater than 10, and in the case of Korean, tens of conjugated words exist for each stem.

Assuming that the key sequence input by a user is in English, the process of generating the above-described recommended word list is described below. Prior to the description, input word character strings are classified into the following six types, and then the process is described:

1) words each composed of only a ‘stem’—for example, about, on, for

2) words each composed of a ‘stem’+a ‘suffix’—for example, nation+alize

3) words each composed of a ‘prefix’+a ‘stem’—for example, re+transmit

4) words each composed of a ‘prefix’+a ‘stem’+a ‘suffix’—for example, inter+nation+alization

5) words (compound words) each composed of a ‘first stem’+a ‘second stem’—for example, credit+card, and

6) words (compound words) each composed of a ‘first stem’+a ‘second stem’+a ‘suffix’

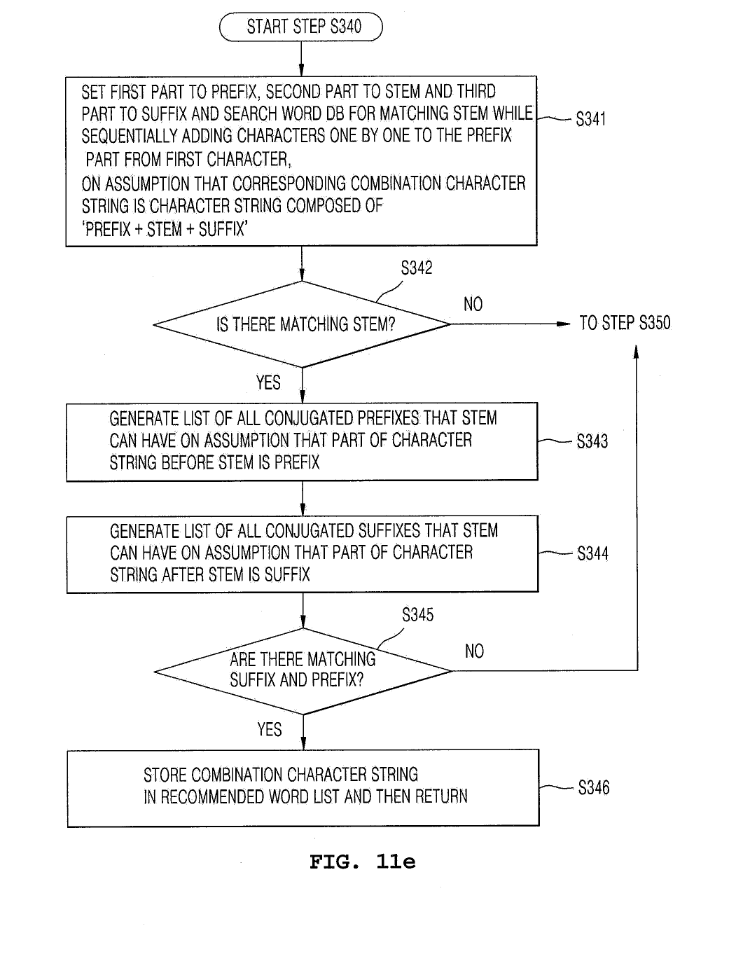

Referring to FIG. 10, illustrating the entire process of generating a recommended word list according to the present invention, the process is divided into step S100, at which the control module 830 of the mobile terminal 800 detects the pressing of a key from the character input device 810A, and adds a character corresponding to the pressing of the key, that is, a character assigned to the key, to a character string buffer; step S200, at which the control module 830 generates combination character strings from respective characters stored in the character string buffer; step S300, at which the control module 830 searches the word database 824 for words matching corresponding combination character strings on the assumption that each of the generated combination character strings is a word having a prefix/stem stem/suffix combination, and generates a recommended word list using the matching corresponding combination character strings; and step S400, at which the control module 830 displays the generated recommended word list on the display device (not shown) of the terminal.

At step S100 is included the step of determining whether the length of the character string is greater than 1 after adding the character to the character string buffer. If the length of the character string is greater than 1, the control module 830 detects the pressing of a key from the character input device 810A until the length of the character string is greater than 1.

Step S200 of generating all possible combination character strings using respective characters stored in the character string buffer is as described above, and another example thereof is as follows. Assuming that the character input device 810 is the right hand-dedicated character input device 300 of FIG. 3a and the character string to be input is ‘YOU’, characters generated by the pressing of keys are ‘Y’, ‘T’, ‘O’, ‘W’, ‘U’, and ‘R’, and character strings obtained through the combination thereof are a total of combination character strings ‘YOU’, ‘YOR’, ‘YWU’, ‘YWR’, ‘TOW’, ‘TOR’, ‘TWU’ and ‘TWR’. Of course, it is self-evident that the number of combination character strings increases in proportion to the length a character string desired to be input. Such combination character strings may be represented in a structural tree form. The structural tree will be described in an embodiment that is applied to the case of Korean below.

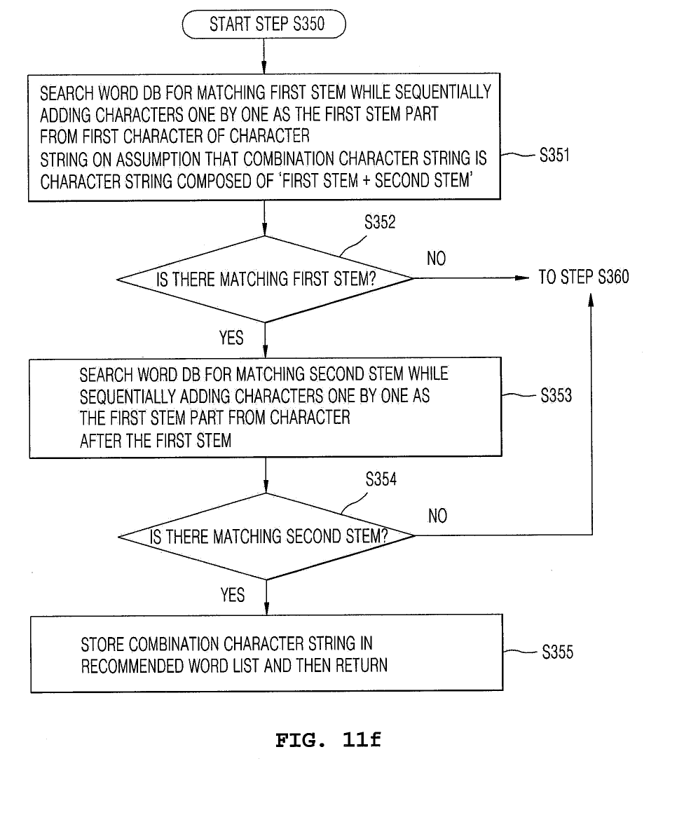

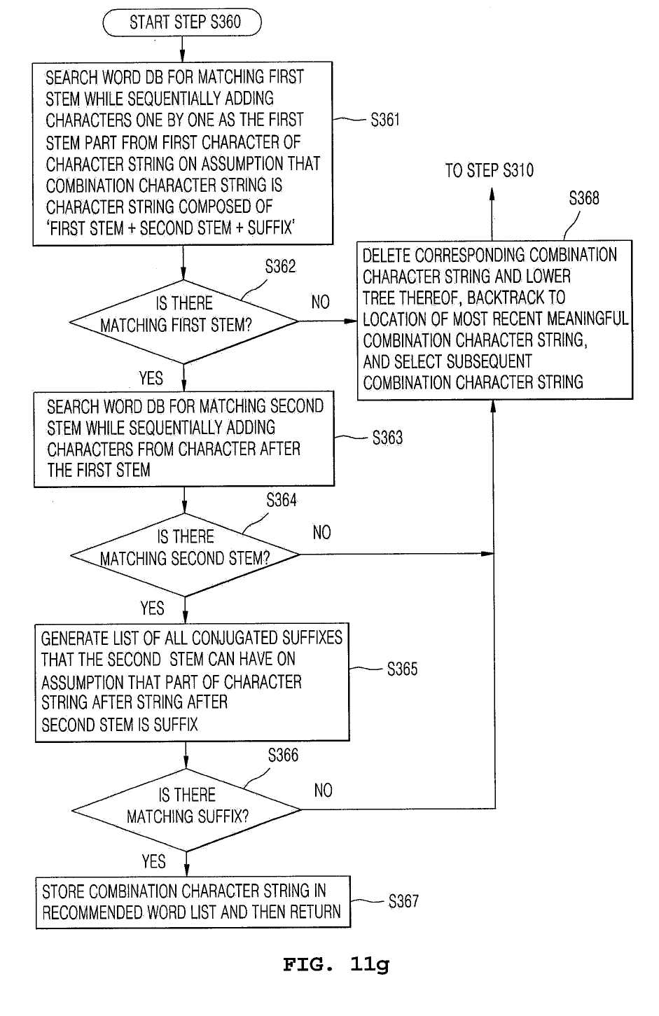

Step S300 is a process of performing sequential processing while applying the above-described six types to each of the combination character strings generated at step S200, and includes step S310 of searching the word database 824 for each of the character strings on the assumption that the combination character string is a character string composed of a ‘stem’, as illustrated in FIG. 11a, and generating a recommended word list if there are matching words; step S320 of, if there is no matching word at step S310, performing searching again on the assumption that the corresponding combination character string is a character string composed of ‘a stem+a suffix’, and generating a recommended word list; step S330 of, if there is no matching word at step S320, performing searching again on the assumption that the corresponding combination character string is a character string composed of ‘a prefix+a stem’, and generating a recommended word list; step S340 of, if there is no matching word at step S330, performing searching again on the assumption that the corresponding combination character string is a character string composed of ‘a prefix+a stem+a suffix’, and generating a recommended word list; step S350 of, if there is no matching word at step S340, performing searching again on the assumption that the corresponding combination character string is a compound-type character string composed of ‘a first stem+a second stem’, and generating a recommended word list; and step S360 of, if there is no matching word at S350 step, performing searching on the assumption that the corresponding combination character string is a compound-type character string composed of ‘a first stem+a second stem+a suffix’, and generating a recommended word list.

As illustrated in FIG. 11b, step S310 includes step S311 of searching the word database 824 for a matching stem (word) on the assumption that the corresponding combination character string is a character string composed of a ‘stem’, and steps S312 and S313 of, if there is no matching stem, storing the corresponding combination character string in a recommended word list and returning. If there is no matching stem, the process returns to step S320.

Here, each of the combination character strings stored in the recommended word list may be stored along with information about the frequency of use of the combination character string. The reason for this is to help a user make a final selection by storing each of the combination character strings along with information about the frequency of use of the combination character string because a plurality of combination character strings may be stored in the recommended word list. In more detail, if a currently input character string is not the first word of a sentence, the value of the frequency of use may be adjusted by searching the word database 824 for the feature values of a character string input as a previous word (the part of speech of a word, and the various features of a word when the word forms a sentence, etc.) and considering the relationship between the previous word and the current word (context). By doing so, a specific word is frequently used. In the state in which a previous word is fixed to a specific word, the sequence of the recommended word list is adjusted in the case where another word is used more frequently, therefore words can be successively input without a user having to select a specific word.

Of course, it is preferred that the frequencies of use and the feature values be previously stored for respective words in the word database 824. Since the frequencies of use and the relationships between words may be applied to steps S320 to S360 in the same manner, descriptions thereof will be omitted below.

Thereafter, step S320, as illustrated in FIG. 11c, includes step S321 of searching the word database 824 for a stem on the assumption that the corresponding combination character string is a character string composed of ‘a stem+a suffix’ at step S321, and step S323 of, if there is a matching stem at step S322, generating a list of all conjugated suffixes that the stem can have on the assumption that the part of the character string other than the matching stem is a suffix. Thereafter, the generated conjugated suffix list is searched for a suffix that matches the assumed suffix at step S324, if there is a matching suffix at step S325, the corresponding combination character string is stored in the recommended word list, and the process returns.

At the step S320, in some cases, the stem may have a substring relationship to another stem. Accordingly, it is preferable to repeatedly search all ‘stem+suffix’ combinations for the corresponding combination character string.

Step S330, as shown in FIG. 11d, assumes that the first part is a prefix and the other part is a stem and searches the word database 824 for a matching stem while sequentially adding characters from the beginning of a character string on the assumption that the corresponding combination character string is a character string composed of ‘a prefix+a stem’ at step S331, and, if there is a matching stem at S332, generates all conjugated prefixes that the stem can have on the assumption that the part of the character string, other than the matching stem, is a prefix at step S333. Thereafter, the process determines whether the assumed prefix is present in the generated conjugated prefixes at step S334, and, if there is a matching prefix, stores the corresponding combination character string in the recommended word list and returns at step S336. If there is no matching stem at step S332 or there is no matching suffix at step S335, the process proceeds to step S340.

Here, since, like the above-described step S320, the stem may have a substring relationship to another stem, it is preferable to sequentially search for all ‘prefix+stem’ combinations for the corresponding combination character string.

Referring to FIG. 11e, step S340 sets a first part to a prefix, a second part to a stem and a third part to a suffix and searches the word database 824 for a matching stem while sequentially adding characters from a first character, on the assumption that the corresponding combination character string is a character string composed of ‘a prefix+a stem+a suffix’ at step S341. If the matching stem is present in the word database 824 at step S342, a list of all conjugated prefixes that the stem can have is generated on the assumption that the part of the character string before the matching stem is a prefix at step S343 and the part of the character string after the matching stem is a suffix at step S344. If the assumed prefix and the assumed suffix are present in the previously generated prefix list and conjugated suffix list at step S345, the process stores the corresponding combination character string in the recommended word list and then returns at step S346. If there is no matching stem at the above-described step and no matching prefix or suffix at steps S342 and S345, the process proceeds to step S350.

Referring to FIG. 11f, step S350 searches the word database 824 for a matching first stem while sequentially adding characters from the first character of the character string on the assumption that the corresponding combination character string is a compound-type character string composed of ‘a first stem+a second stem’ at step S351, and, if there is a matching first stem at step S352, searches the word database 824 for a matching second stem while sequentially adding characters from the character after the first stem at step S353. If a matching second stem is present in the word database 824 at step S354, the process stores a corresponding combination character string in the recommended word list and then returns at step S355. If there is no matching first stem at the above-described step S352 and there is no matching second stem at step S354, the process proceeds to step S360.

Finally, step S360, as illustrated in FIG. 11g, searches the word database 824 for a matching first stem while sequentially adding characters from the first character of the character string on the assumption that the corresponding combination character string is a compound-type character string composed of ‘a first stem+a second stem+a suffix’ at step S361. Thereafter, if a matching first stem is present in the word database 824 at step S362, the word database 824 is searched for a matching second stem while characters are sequentially added from the character after the first stem at step S363, and, if there is a matching second stem at step S364, a list of all conjugated suffixes that the second stem can have is generated on the assumption that the part after the second stem is a suffix at step S365. If the assumed suffix is present in the generated conjugated suffix list at step S366, the corresponding combination character string is stored in the recommended word list and then the process returns at step S367. Meanwhile, in the case where there is no matching first stem at the above-described step S362, there is no matching second stem at step S364, and there is no matching suffix at step S366, it is determined that the corresponding character string is not a meaningful character string, the corresponding combination character string and the lower tree thereof are deleted, backtracking to the location of the most recent meaningful combination character string is performed, and a subsequent combination character string is selected at step S368.

Up to now, the process of generating a recommended word list has been made on the assumption that the key sequence input by a user is in English. The recommended word list generated after this process is output through the display device (not shown) of the mobile terminal 800. At this time, the character strings of the recommended word list may be arranged in descending sequence of frequency of use as described above. If the character string indicated in the uppermost part of the recommended word list is the character string desired to be input, a user selects the character string indicated in the uppermost part by pressing a space key (the key ‘SPACE’ shown in FIG. 3a). If the character string desired to be input is present in a lower part, other than the uppermost part, the character string can be selected by moving the corresponding character string to the uppermost part by pressing an ‘Alt’ key (key ‘ALT’ shown in FIG. 3a) and then pressing a space key.

Furthermore, the above-described step S300 is a so-called ‘word-level definition mode’. It is preferred that step S300 be performed whenever a user presses a key until he or she presses a space key (here, the phase “pressing of the space key” means the termination of input of a character string), and that the recommended word list be updated in real time whenever the user presses a key.

Through the recommended word list arranged according to the frequency of use as described above, the number of presses of keys and presses of a space key, in other words, except for the number of presses of keys for general character input, become less than 1, even though the number of times user definitely presses the ‘Alt’ key is taken into consideration.

Meanwhile, if the character string input by the user is not a word that is registered in the word database 824, the character string intended to be input by the user is not included in the recommended word list. In this case, by pressing an ESCAPE key (not shown) separately provided in the character input device 810A, the user can exit from the ‘word-level definition mode’ and then input the character string in a ‘character-level definition mode’. The term ‘character-level definition mode’ refers to a process in which a user positively indicates the intended character by pressing the ‘Alt’ key after each input character. By doing so, a user can input a new word character string that has been previously registered in the word database 824, and furthermore the user can add the input new word to the word database 824.

Most of the above-described process can be applied to Korean. However, in general, Korean has many cases where users do not accurately space words, unlike English. Provided that a user inputs Korean words according to the rules of Korean orthography, the process of generating a recommended word list can be simplified. However, most of the cases are otherwise. It is preferable to assume that a word and a word, or a character string and a character may be combined with each other. Furthermore, since a large number of Korean words can be successively combined with each other, unlike an English compound word, in which only two words are combined with each other, ‘phrase-level definition’ must be considered, therefore the amount of computational work for searching all combinations of words is estimated to be considerably larger than that for English, with the result that the process requires additional processing steps, unlike in the case of English.

A process of generating a recommended word list in the case where the key sequence input by the user is Korean is described in greater detail below with reference to the accompanying drawings.

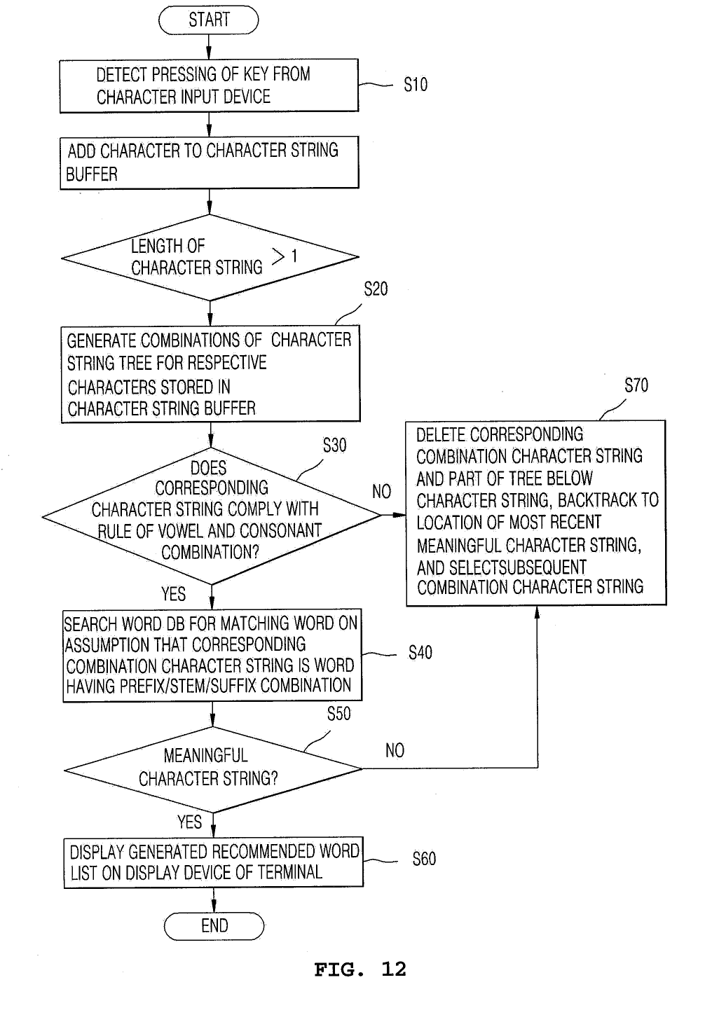

Referring to FIG. 12, the control module 830 detects the pressing of a key from the character input device 810A and adds a character corresponding to the pressing of the key (a character assigned to the pressed key) to the character string buffer at step S10. Here, the character input device 810A may be the right hand-dedicated character input device 500 shown in FIG. 5, or the left hand-dedicated character input device 600 shown in FIG. 6. After the adding of the character, assigned to the pressed key, to the character string buffer, the step of determining whether the length of the character string is larger than 1 may be further included.

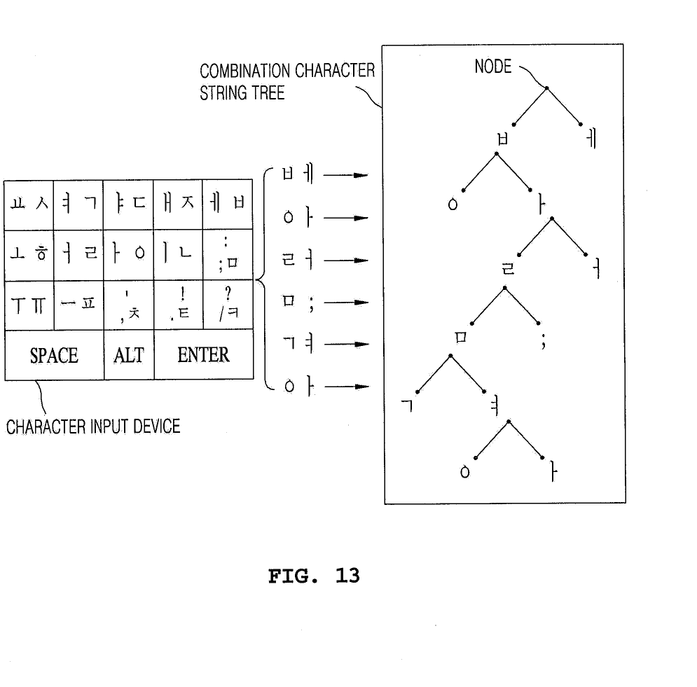

Thereafter, a combination character string is generated for respective characters stored in the character string buffer (preferably, characters assigned to pressed keys) at step S20. In this case, the combination character string is generated through the same process as the case of English. Illustrating the process in a structural fashion (in a tree form) to facilitate the following description on the assumption that the character string desired to be input is ‘ [symbol] ’, the process may be illustrated as shown in FIG. 13. This structure is referred to as a combination character string tree (Depth First Traversal Tree). This combination character string tree is applied to the above-described case of English in the same manner.

Thereafter, whether a first combination character string in a combination character string tree complies with the rule of Korean vowel and consonant combination is examined at step S30. As is well known, the rule governing the combination of Korean vowels and consonants is a rule that uses the special feature of Korean, and prescribes that the fundamental combination of a vowel and consonants of each word should be ‘initial sound+medial sound+final sound’ or ‘initial sound+medial sound’. For example, an initial sound must be a consonant (which may be a compound consonant, such as ‘ [symbol] ’), a vowel (which may be a compound vowel, such as ‘ [symbol] ’) should be placed after the initial sound, and finally a consonant should be placed at the location of the final consonant.

Step S30, if the corresponding combination character string complies with the rule of vowel and consonant combination, searches the word database 824 for a word that matches the assumed word on the assumption that the corresponding combination character string is a word having a prefix/stem/suffix combination at step S40. If there is a matching word, it is determined that the corresponding character string is a meaningful character string at step S50, and the corresponding character string is stored in the recommended word list and is displayed on the display device (not shown) of the mobile terminal 800 at step S60.

Meanwhile, if, as a result of the determination at step S30, the corresponding combination character string does not comply with the rule of vowel and consonant combination, the process deletes the corresponding combination character string and the part of a tree below the character string, moves to the location of the most recent meaningful character string (hereinafter referred to as ‘Backtracking’) and selects a subsequent combination character string at step S70, and returns to step S30 step. If, as a result of the determination at step S50, the corresponding combination character string is not a meaningful character string, the process returns to the above-described step S70.

Through the above-described steps S30 to S50 and step S70, in other words, the application of the rule of vowel and consonant combination to the combination character string and backtracking, the entire processing time can be considerably reduced. In more detail, with the above-described character string ‘ [symbol] ’ taken as an example (refer to FIG. 13), a user presses keys of the character input device 810A six times (for initial sound+median sound+final sound+initial sound+median sound+final sound) so as to input the word ‘ [symbol] ’, therefore 64 combination character strings are formed. When the rule of vowel and consonant combination is applied to ‘ [symbol] ’ and ‘ [symbol] ’ located below the uppermost node of a combination character tree, it is not necessary to examine combination character strings related to the part of the tree below ‘ [symbol] ’ because a vowel cannot be placed at the location of an initial sound. As a result, 32 combination character strings corresponding to half of a total of 64 combination character strings can be deleted. When backtracking to the uppermost node is performed, ‘ [symbol] ’ and ‘ [symbol] ’ are located below node ‘ [symbol] ’. Since a vowel cannot be placed at the location of a medial sound next to an initial sound, combination character strings related to the part of the tree below vowel ‘ [symbol] ’ can be deleted. When backtracking to ‘ [symbol] ’ node is performed, ‘ [symbol] ’ and ‘ [symbol] ’ are located below ‘ [symbol] ’ node. Since a vowel must be placed at the location of a final sound, combination character strings related to the part of the tree below ‘ [symbol] ’ node can be deleted. When backtracking to ‘ [symbol] ’ node is performed, ‘ [symbol] ’ and ‘ [symbol] ’ are located below ‘ [symbol] ’ node. Since a vowel must be placed at the location of an initial sound according to the above-described principle, combination character strings related to the part of the tree below ‘ [symbol] ’ node can be deleted. When backtracking to ‘ [symbol] ’ node is performed, ‘ [symbol] ’ and ‘ [symbol] ’ are located below ‘ [symbol] ’ node. Since a vowel must be placed at the location of a median sound, combination character strings related to the part of the tree below ‘ [symbol] ’ node can be deleted. Finally, when backtracking to ‘ [symbol] ’ node is performed, ‘ [symbol] ’ and ‘ [symbol] ’ are located below ‘ [symbol] ’ node. According to the above-described final sound requirement, vowel ‘ [symbol] ’ can be deleted.

From the above-described example, it can be seen that the number of steps and the amount of processing are considerably reduced through the rule of vowel and consonant combination and backtracking according to the present invention.

Although the description and the illustration have been provided in conjunction with the preferred embodiment for the illustration of the technical spirit of the present invention, the present invention is not limited to the illustrated and described construction and operation, but those skilled in the art can appreciate that various variations and modifications are possible without departing from the scope of the spirit of the present invention. Accordingly, all appropriate variations, modifications and equivalents must be considered to fall within the scope of the present invention.

### INDUSTRIAL APPLICABILITY

According to the above-described present invention, characters can be rapidly and accurately input in a touch typing manner even in a mobile environment, and the number of presses of keys for the input of a single character can be minimized.

Furthermore, according to the present invention, how to use thereof can be easily acquired by adopting a mirror-image symmetrical character arrangement based on the ‘Sholes’ character arrangement.

1-4. (canceled)

5. A character input device for a terminal, comprising a plurality of character keys and a function key, wherein the character keys include a character arrangement corresponding a first half of a ‘Sholes’ character arrangement with respect to a center of the ‘Sholes’ character arrangement, a character arrangement of a second half of the Sholes’ character arrangement being arranged on the character keys at locations mirror-image symmetrical to the first half with respect to the center of the Sholes’ character arrangement, a memory unit for storing a control program, used to control the character input device, and a word database, and a control module for controlling the character input device based on the control program, the method comprising:
step S100 of adding characters, arranged on respective pressed keys, to a character string buffer when an English key sequence is input through the character input device;
step S200 of generating combination character strings from the characters added to the character string buffer;
step S300 of searching the word database for words matching corresponding combination character strings on an assumption that each of the generated combination character strings is a word having a prefix/stem/suffix combination, and generating a recommended word list using the matching corresponding combination character strings; and
step S400 of displaying the generated recommended word list on a display device of the terminal.

6. The character input device as set forth in claim 5, wherein the word database comprises frequencies of use of words, and attribute values including parts of speech and various sentence constitution features of the words;
meaningful combination character strings of the recommended word list being arranged in descending sequence of probability of general intention of a user according to contextual relationship to the word input before the current key sequence, based on frequencies of use and attribute values.

7. The method as set forth in claim 5, wherein the step S300 comprises step S310 of searching the word database for each of the combination character strings on an assumption that the combination character string is a character string composed of a ‘stem’, and generating a recommended word list if there are matching words; step S320 of, if there is no matching word at step S310, performing searching again on an assumption that the corresponding combination character string is a character string composed of ‘a stem+a suffix’, and generating a recommended word list; step S330 of, if there is no matching word at step S320, performing searching again on an assumption that the corresponding combination character string is a character string composed of ‘a prefix+a stem’, and generating a recommended word list; step S340 of, if there is no matching word at step S330, performing searching again on an assumption that the corresponding combination character string is a character string composed of ‘a prefix+a stem+a suffix’, and generating a recommended word list; step S350 of, if there is no matching word at step S340, performing searching again on an assumption that the corresponding combination character string is a compound type character string composed of ‘a first stem+a second stem’, and generating a recommended word list; and step S360 of, if there is no matching word at S350 step, performing searching on an assumption that the corresponding combination character string is a compound type character string composed of ‘a first stem+a second stem+a suffix’, and generating a recommended word list.

8. The method as set forth in claim 7, wherein the step S310 comprises step S311 of searching the word database for the matching stem on an assumption that the corresponding combination character string is a character string composed of a ‘stem’, step S312 of determining whether there is a matching stem; S313 of, if there is no matching stem, storing the corresponding combination character string in a recommended word list, and then returning; and, if there is no matching stem, returning to the step S320.

9. The method as set forth in claim 7, wherein the step S320 comprises step S321 of searching the word database for the stem, step S322 of determining whether there is a matching step, step S323 of, if there is a matching stem, generating a list of all conjugated suffixes that the stem can have on an assumption that a part of the character string other than the matching stem is a suffix, step S324 of searching the conjugated suffixes for the assumed suffix, step S325 of determining whether there is a matching suffix, step S326 of, if there is a matching suffix, storing the corresponding combination character string in the recommended word list, and then returning; and the step of, if there is no matching stem at step S322 or if there is no matching suffix at step S325, returning to the step S330.

10. The method as set forth in claim 7, wherein the step S330 comprises step S331 of searching the word database for the stem; step S332 of determining whether there is a matching stem; step S333 of, if there is a matching stem, generating all conjugated prefixes that the stem can have on an assumption that a part of the character string, other than the matching stem, is a prefix; step S334 of determining whether there is a conjugated prefix that matches the prefix; step S335 of determining whether there is a matching prefix; step S336 of, if there is a matching prefix, storing the corresponding combination character string in the recommended word list and returning; and the step of, if there is no matching stem at step S332 or there is no matching prefix at step S335, proceeding to the step S340.

11. The method as set forth in claim 7, wherein the step S340 comprises step S341 of searching the word database for the matching stem; step S342 of determining whether there is a matching stem; step S343 of, if there is a matching stem, generating a list of all conjugated prefixes that the stem can have on an assumption that a part of the character string before the matching stem is a prefix; step S344 of generating a list of all conjugated suffixes that the stem can have on an assumption that a part of the character string after the matching stem is a suffix; step S345 of determining whether the assumed prefix and the assumed suffix are present in the conjugated prefix list and the conjugated suffix list; step S346 of, if there are a matching prefix and a matching suffix, storing the corresponding combination character string in the recommended word list and returning; and the step of, if there is no matching stem at the above-described step and there is no matching prefix or suffix at steps S346, proceeding to the step S350.

12. The method as set forth in claim 7, wherein the step S350 comprises step S351 of searching the word database for the matching first stem; step S352 of determining whether there is a matching first stem; step S353 of, if there is a matching first stem, searching the word database for a matching second stem on an assumption that a part of the character string after the first stem is a second stem, step S354 of determining whether there is a matching second stem, step S355 of, if there is a matching second stem, storing the corresponding combination character string in the recommended word list and then returning; and the step of, if there is no matching first stem at the step S352 or there is no matching second stem at the step S354, proceeding to the step S360.

13. The method as set forth in claim 7, wherein the step S360 comprises step S361 of searching the word database for the matching first stem, step S362 of determining whether there is a matching first stem; step S363 of, if there is a matching first stem, searching the word database for a matching second stem; step S364 of determining whether there is a matching second stem; step S365 of, if there is a matching second stem, generating a list of all conjugated suffixes that the second stem can have; step S366 of determining whether there is a matching suffix; step S367 of, if there is a matching suffix, storing the corresponding combination character string in the recommended word list, and then returning; and step S368 of, if there is no matching first stem at the step S362, there is no matching second stem at the step S364, or there is no matching suffix at the step S366, deleting the corresponding character string and a part of a tree below the corresponding character string, backtracking to a location of a most recent meaningful combination character string, selecting a subsequent combination character string, and then returning to the step S310.

14. A character input device for a terminal, comprising a plurality of character keys and a function key, wherein the character keys include a character arrangement corresponding a first half of a ‘Sholes’ character arrangement with respect to a center of the ‘Sholes’ character arrangement, a character arrangement of a second half of the Sholes’ character arrangement being arranged on the character keys at locations mirror-image symmetrical to the first half with respect to the center of the Sholes’ character arrangement, a memory unit for storing a control program, used to control the character input device, and a word database, and a control module for controlling the character input device based on the control program, the method comprising:
step S10 of adding characters, arranged on respective pressed keys, to a character string buffer when a Korean key sequence is input through the character input device, step S20 of generating a combination character string tree from the characters added to the character string buffer, step S30 of examining whether combination character strings of the combination character string tree comply with a rule of vowel and consonant combination; step S70, if the combination character string does riot comply with the rule of vowel and consonant combination, deleting a part of a tree below the combination character string, backtracking to a location of a most recent meaningful character string, selecting a subsequent combination character string, and then returning to the step S30; step S40 of, if the combination character string complies with the rule of vowel and consonant combination at step S30, searching the word database for a word that matches the assumed word on an assumption that the corresponding combination character string is a word having a prefix/stem/suffix combination; step S50 of determining whether there is a matching word at the step S40, step S60, if, as a result of the determination at step S50, there is a matching word, adding the corresponding character string to the recommended word list, and displaying the combination character string on a display device of the mobile terminal; and the step of, if, as a result of the determination at the step S50, there is no matching word, returning to the step S70.

15. The method as set forth in claim 14, wherein the word database comprises frequencies of use of words, and attribute values including parts of speech and various sentence constitution features of the words;
meaningful combination character strings of the recommended word list being arranged in descending sequence of probability of general intention of a user according to relationship (context) to words, input before the key sequence, based on frequencies of use and attribute values.
